(19) United States
(12) Patent Application Publication
(10) Pub. No.: US 2015/0091021 A1
(43) Pub. Date: Apr. 2, 2015

(54) Method of Manufacturing Semiconductor Device and the Semiconductor Device

(71) Applicant: Sanken Electric Co., LTD., Niiza-shi (JP)

(72) Inventor: Toru Yoshie, Niiza-shi (JP)

(73) Assignee: SANKEN ELECTRIC CO., LTD., Niiza-shi (JP)

(21) Appl. No.: 14/496,339

(22) Filed: Sep. 25, 2014

(30) Foreign Application Priority Data
Sep. 30, 2013 (JP) 2013-204875

(51) Int. Cl. H01L 29/49; H01L 21/311; H01L 29/45; H01L 21/285; H01L 21/28; H01L 29/16

(52) U.S. Cl. CPC H01L 29/4941; H01L 21/28044; H01L 29/1608; H01L 29/45; H01L 21/28518; H01L 21/31144
USPC 257/77; 438/586

(57) ABSTRACT

A method of manufacturing a semiconductor device includes: forming a gate electrode material layer made of a material configuring a gate electrode and a barrier material layer made of a silicon nitride film; forming an upper barrier layer configured to an upper surface of the gate electrode with the barrier material layer and forming the gate electrode from the gate electrode material later by etching the barrier material layer and the gate electrode material layer with a same mask pattern; forming a sidewall barrier layer configured to cover a side surface of the gate electrode by forming again the barrier material layer after the forming of the gate electrode; forming an interlayer insulation layer configured to cover a surface-side of the semiconductor substrate including the upper surface barrier layer and the sidewall barrier layer; and opening the interlayer insulation layer and forming the silicide electrode.

### CROSS-REFERENCE TO RELATED APPLICATION

This application claims priority from Japanese Patent Application No. 2013-204875 filed on Sep. 30, 2013, the entire subject matter of which is incorporated herein by reference.

### TECHNICAL FIELD

This disclosure relates to a method of manufacturing a semiconductor device in which a silicide electrode is used for a contact with a semiconductor substrate, and a structure of the semiconductor device.

### BACKGROUND ART

In a MOSFET (Metal Oxide Semiconductor Field Effect Transistor), a gate oxide film and a gate electrode are formed on a semiconductor substrate, and a source region and a drain region, which are diffusion layers, are formed at both sides of the gate electrode. At this time, sidewalls made of SiO₂ and the like may be formed on both sides (sides facing the source region and the drain region) of the gate electrode, in many cases. Also, in many cases, a silicide electrode, which is a compound of metal and silicon, is used for a contact between the source electrode and the source region and between the drain electrode and the drain region so as to reduce a contact resistance. The silicide electrode is effective for reduction of the contact resistance. However, when the metal (for example, Ni) configuring the silicide diffuses into the gate electrode or gate oxide film, it has a negative influence on characteristics of the MOSFET.

For this reason, JP-A-H11-317527 discloses a structure where a gate electrode is surrounded by a multi-layered structure of SiO₂ and SiN. By this structure, it is possible to reduce the negative influence of the metal, which configures the silicide electrode, on the characteristics of the MOSFET.

Also, particularly, a power semiconductor device for which silicon carbide (SiC) is used is effective. As disclosed in JP-A-2009-94203, in a case where a semiconductor substrate is made of SiC, manufacturing processes thereof are largely different from a case where the semiconductor substrate is made of silicon (Si), even though the structures thereof are the same. When the semiconductor substrate is made of silicon, a gate oxide film and a gate electrode are formed on the semiconductor substrate, the gate electrode is patterned, ion implantation is performed using the patterned gate electrode as a mask and a heat treatment is performed to form a source region and a drain region on the semiconductor substrate. In contrast, when the semiconductor substrate made of SiC is used, the heat treatment condition upon the formation of the source region and the drain region is a very high temperature. Therefore, it is difficult to form the gate electrode and the like before forming the source region and the drain region. For this reason, it is necessary to first form the source region and the drain region and then to form the gate oxide film and the gate electrode.

In any case, after the gate electrode, the source region and the drain region are formed, an interlayer insulation layer configured to cover the gate electrode is formed. The interlayer insulation layer opens on the source region and the drain region, and silicide electrodes are formed on the semiconductor layer exposed through the openings. The interlayer insulation layer is made of an insulating material such as BPSG (Borophosphosilicate glass) having a main component of SiO₂. As described above, in order to suppress the negative influence of the metal configuring the silicide, the opening (a contact part between the semiconductor layer and the silicide electrode) is necessarily spaced from the gate electrode, and the interlayer insulation layer mainly exists between the gate electrode and the contact part. According to the technology disclosed in JP-A-H11-317527, the interlayer insulation layer has a multi-layered structure and a silicon nitride film (SiN) having a higher barrier characteristic than SiO₂ is also included in the multi-layered structure. Thereby, it is possible to reduce the negative influence of the metal, which configures the silicide electrode, on the characteristics of the MOSFET.

### SUMMARY

In the above structure, although the interlayer insulation layer is formed, the metal (for example, Ni) configuring the silicide reacts with SiO₂ configuring the interlayer insulation layer, so that a new silicide reaction or a reaction generating NiOₓ and the like may occur at an interface of the silicide and the interlayer insulation layer. For this reason, even when the interlayer insulation layer is interposed, it is difficult to reduce the negative influence of the metal, which configures the silicide, on the gate electrode and gate oxide film. The influence is particularly appeared when SiC, which requires the high temperatures for a variety of heat treatments, is used.

As described above, when forming the MOSFET on the semiconductor substrate, it is difficult to reduce the negative influence of the metal configuring the silicide electrode.

In view of the above, this disclosure is to provide at least a method of manufacturing a semiconductor device and a semiconductor device.

Aspects of the illustrative embodiments of this disclosure will be described.

A method of manufacturing a semiconductor device includes a gate oxide film, which is formed on a surface of a semiconductor substrate; a main electrode, which is formed on the surface and a current flowing through which is switched by a voltage applied to a gate electrode formed on the gate oxide film; and a silicide electrode is provided between the main electrode and the surface. The method includes: forming, sequentially, a gate electrode material layer made of a material configuring the gate electrode and a barrier material layer made of a silicon nitride film, on the gate oxide film; forming an upper barrier layer configured to an upper surface of the gate electrode with the barrier material layer and forming the gate electrode from the gate electrode material later by etching the barrier material layer and the gate electrode material layer with a same mask pattern; forming a sidewall barrier layer configured to cover a side surface of the gate electrode by forming again the barrier material layer after the forming of the gate electrode from the gate electrode material later; forming an interlayer insulation layer configured to cover a surface-side of the semiconductor substrate including the upper surface barrier layer and the sidewall barrier layer; and opening the interlayer insulation layer and then forming the silicide electrode on the surface of the semiconductor substrate.

In the above-described method, in the forming of the sidewall barrier layer, the barrier material layer may be etched back after forming again the barrier material layer.

In the above-described method, in the forming of the gate electrode from the gate electrode material later, the gate oxide film may be etched by using the same mask pattern after the etching of the gate electrode material layer.

In the above-described method, the semiconductor substrate may be made of silicon carbide.

In the above-described method, the silicide electrode may be made of nickel silicide.

A semiconductor device may be manufactured by the method of manufacturing the semiconductor device according to above-described method.

A semiconductor device of another aspect includes: a gate oxide film, which is formed on a surface of a semiconductor substrate; a main electrode, which is formed on the surface and a current flowing through which is switched by a voltage applied to a gate electrode formed on the gate oxide film; and a silicide electrode is provided between the main electrode and the surface, wherein an upper surface of the gate electrode and a side surface of the gate electrode facing the silicide electrode are covered by a barrier layer made of a silicon nitride film.

In the above-described semiconductor device, the barrier layer on the upper surface of the gate electrode may be thicker than the barrier layer on the side surface.

In the above-described semiconductor device, the semiconductor substrate may be made of silicon carbide.

In the above-described semiconductor device, the silicide electrode may be made of nickel silicide.

According to the above configurations, it is possible to reduce the negative influence of the metal configuring the silicide electrode when forming the MOSFET on the semiconductor substrate.

### BRIEF DESCRIPTION OF THE DRAWINGS

The foregoing and additional features and characteristics of this disclosure will become more apparent from the following detailed descriptions considered with the reference to the accompanying drawings, wherein:

FIG. 1 is a sectional view of a semiconductor device according to an illustrative embodiment of this disclosure;

FIGS. 2A to 2N are process sectional views illustrating a method of manufacturing the semiconductor device according to the illustrative embodiment of this disclosure; and

FIG. 3 is a sectional view illustrating a modified embodiment of the semiconductor device according to the illustrative embodiment of this disclosure.

### DETAILED DESCRIPTION

Hereinafter, a semiconductor device according to an illustrative embodiment of this disclosure will be described. The semiconductor device is a MOSFET in which a current flowing between a source electrode and a drain electrode is switched (on-and-off control) by a gate electrode formed on a semiconductor substrate. The MOSFET is formed using a semiconductor substrate made of SiC.

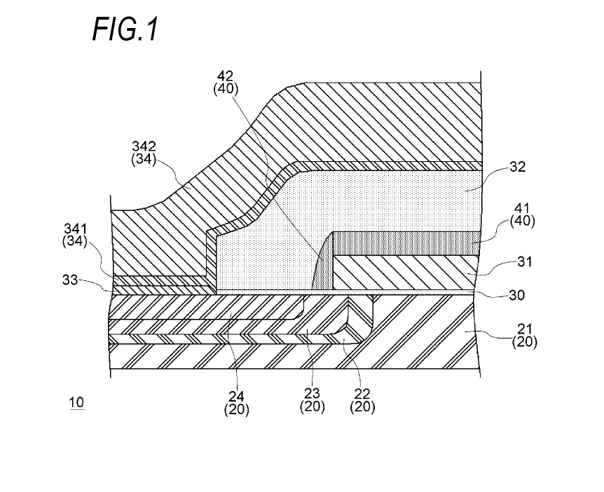

FIG. 1 is a sectional view illustrating a structure of a semiconductor device

(MOSFET) 10. In the semiconductor device 10, a semiconductor substrate 20 made of SiC and having an n-type layer 21 formed on a surface thereof is used. A p-type diffusion layer 22 is locally formed in the n-type layer 21. In the p-type diffusion layer 22, an n⁺-type diffusion layer 23 of an n-type having a higher carrier concentration than the n-type layer 21 is formed. In the n⁺-type diffusion layer 23, an n⁺⁺-type diffusion layer 24 of an n-type having a higher carrier concentration than the n⁺-type diffusion layer 23 is formed. The n-type layer 21 is formed on an n⁺-type substrate (not shown) by an epitaxial growth. The p-type diffusion layer 22, the n⁺-type diffusion layer 23 and the n⁺⁺-type diffusion layer 24 are respectively formed by a heat treatment after ion implantations. The n-type layer 21 becomes a drain region of the MOSFET and the n⁺-type diffusion layer 23 becomes a source region of the MOSFET.

A gate oxide film 30 is formed to cover the p-type diffusion layer 22 between the n-type layer 21 and the n⁺ diffusion layer 23 on the surface of the semiconductor substrate 20. A gate electrode 31 made of polycrystalline silicon, which is heavily doped to be conductive, is formed on the gate oxide film 30. By a voltage applied to the gate electrode 31, a channel is induced on a surface of the p-type diffusion layer 22 below the gate electrode 31 and the switching (on-and-off) of the current is thereby controlled.

Here, an upper surface and side surfaces of the gate electrode 31 are respectively covered by a barrier layer 40. The barrier layer 40 consists of a silicon nitride film (SiN). Here, SiN means an insulating silicon nitride and is a material having a composition of SiₓN_{y} represented by Si₃N₄. The barrier layer 40 has an upper surface barrier layer 41 on the upper surface of the gate electrode 31 and a sidewall barrier layer 42 on the side surfaces of the gate electrode 31. The upper surface barrier layer 41 and the sidewall barrier layer 42 are respectively formed by different processes.

An interlayer insulation layer 32 is formed to cover the barrier layer 40 (the gate electrode 31) and a periphery thereof. The interlayer insulation layer 32 is opened on the n⁺⁺-type diffusion layer 24 (the source region). In the opening, a silicide electrode 33 is formed. The silicide electrode 33 is formed of Ni silicide (NiSi, NiSi₂ and the like), and a contact resistance between the silicide electrode 33 and the n⁺⁺-type diffusion layer 24 is low. A source electrode 34 is formed to cover an entire surface of the structure. The source electrode 34 has a two-layered structure in which a lower layer is a Ti layer 341 and an upper layer is an Al layer 342. Meanwhile, FIG. 1 shows that the source electrode 34 is formed over the entire surface. Actually, however, a patterning is made on the surface of the semiconductor substrate 20 so that the source electrode 34 and the gate electrode 31 are separated and taken out. Also, although a drain electrode is not shown in FIG. 1, the drain electrode is also directly or indirectly connected to the n-type layer 21 and is appropriately taken out from the surface or backside of the semiconductor substrate 20. The interlayer insulation layer 32 is also appropriately patterned in correspondence to the source and drain electrodes.

In the semiconductor device 10, diffusion of the metal (Ni) configuring the silicide electrode 33 to the gate electrode 31 and the gate oxide film 30 is suppressed by the barrier layer 40 having a high barrier characteristic. At this time, the diffusion from the upper surface of the gate electrode 31 is suppressed by the upper surface barrier layer 41 and the diffusion from the side surfaces thereof is suppressed by the sidewall barrier layer 42. Therefore, it is possible to improve the reliability of the semiconductor device 10.

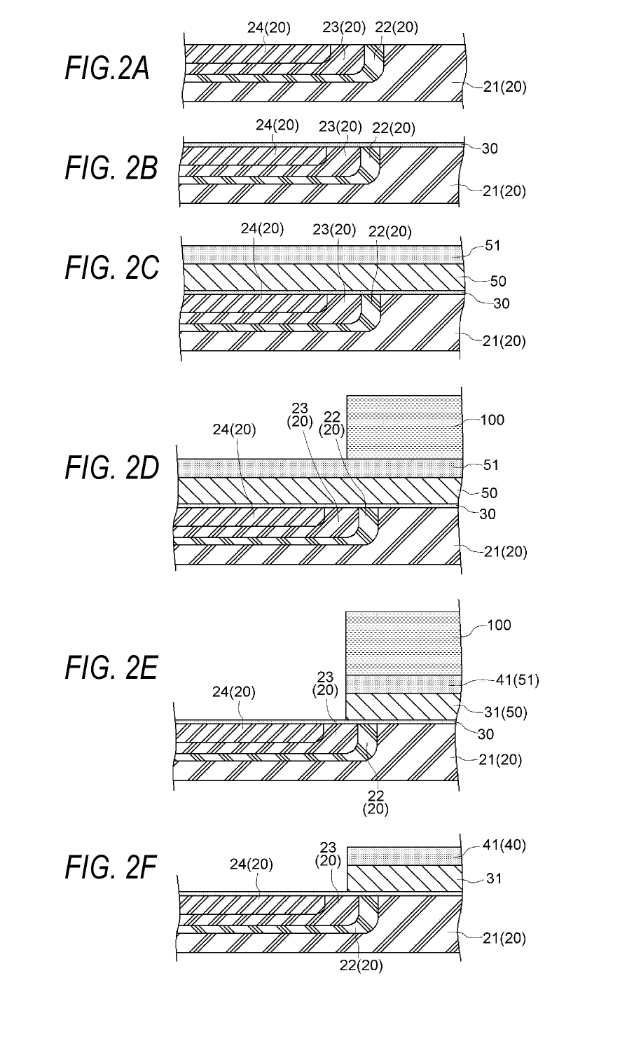

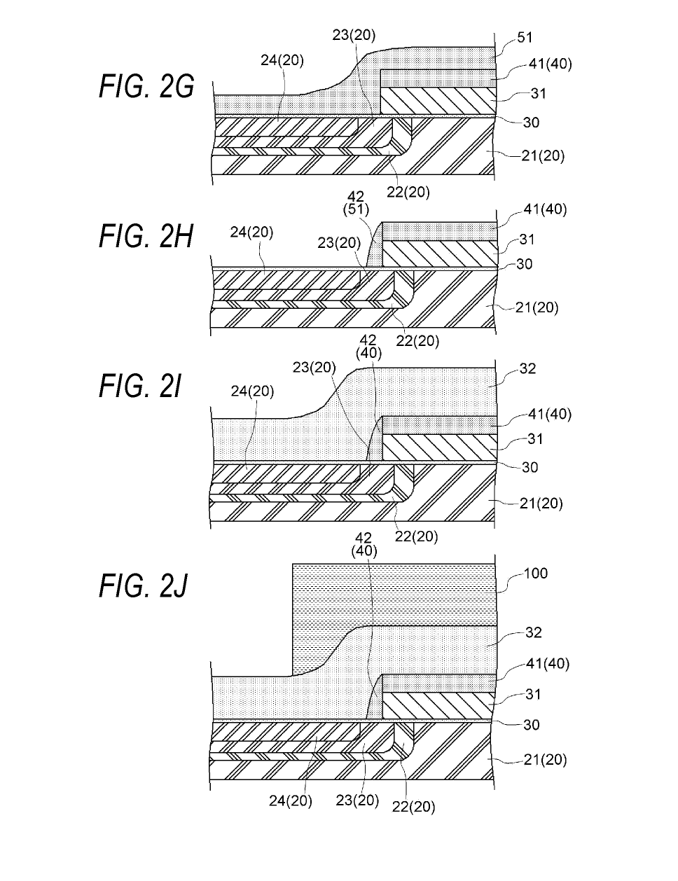

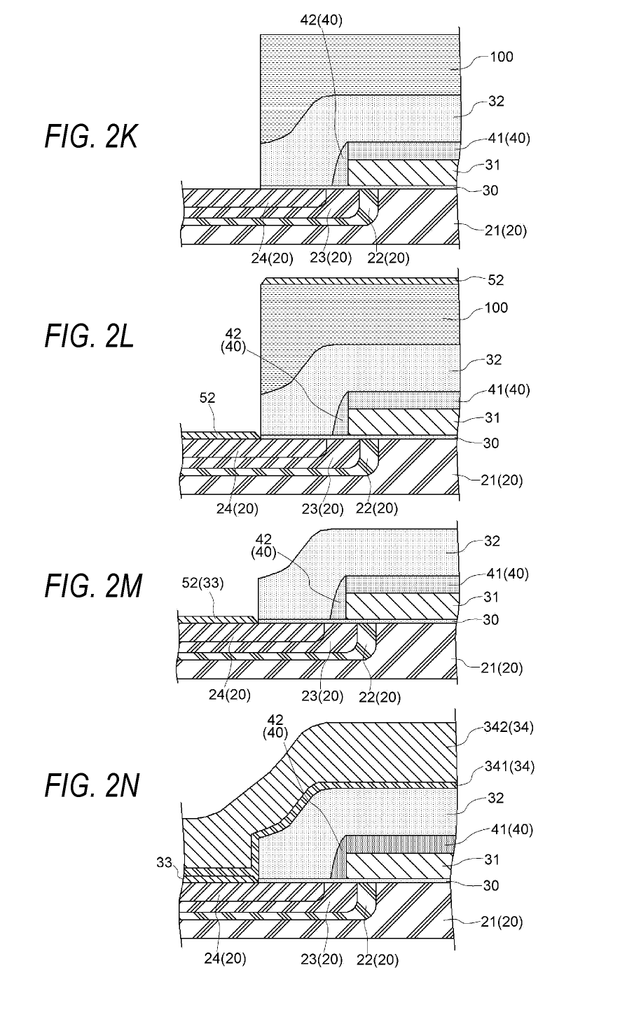

Also, the semiconductor device 10 can be easily manufactured by a following manufacturing method. FIGS. 2A to 2F, FIGS. 3G to 3J and FIGS. 4K to 4N are process sectional views showing the manufacturing method.

First, as shown in FIG. 2A, the p-type diffusion layer 22, the n⁺-type diffusion layer 23 and the n⁺⁺-type diffusion layer 24 are respectively formed in the surface of the semiconductor substrate 20 made of SiC and having the n-type layer 21 formed on the surface. Here, the n-type layer 21 is formed on the n⁺-type substrate (not shown) by an epitaxial growth, for example. The p-type diffusion layer 22, the n⁺-type diffusion layer 23 and the n⁺⁺-type diffusion layer 24 are formed by a heat treatment after ion implanting p-type impurities (Al and the like) and n-type impurities (P, N and the like) thereon with the desired energy and dosage.

Then, as shown in FIG. 2B, the gate oxide film 30 is formed on the semiconductor substrate 20 configured as described above (a gate oxidation process). Here, the gate oxide film 30 has SiO₂, as a main component, and is formed by heat treating (thermally oxidizing) the semiconductor substrate 20 in an oxygen atmosphere.

Then, as shown in FIG. 2C, a gate electrode material layer 50 made of the material (polycrystalline silicon) of the gate electrode 31 is formed on the gate oxide film 30. Further, a barrier material layer 51 made of the material (SiN) configuring the barrier layer 40 is formed thereon (a gate electrode film formation process). The film formation can be performed by a CVD method and the like.

Subsequently, as shown in FIG. 2D, a photoresist layer 100 corresponding to the pattern of the gate electrode 31 is formed. Thereafter, as shown in FIG. 2E, the barrier material layer 51 and the electrode material layer 50 are sequentially dry-etched using the photoresist layer 100 as a mask. Thereby, the barrier material layer 51 and the electrode material layer 50 are shaped by the same mask pattern corresponding to the photoresist layer 100 (a gate electrode shape forming process). Then, as shown in FIG. 2F, the photoresist layer 100 is removed. Thereby, the barrier material layer 51 becomes the upper surface barrier layer 41 and the electrode material layer 50 becomes the gate electrode 31.

Then, as shown in FIG. 2G, the barrier material layer 51 is again formed on the above structure. At the state shown in FIG. 2C, the barrier material layer 51 is formed on the planar shape. In contrast, in this case, the barrier material layer 51 is formed on the semiconductor substrate 20 having a step, which is generated as the upper surface barrier layer 41 and the gate electrode 31 are formed. At this time, the barrier material layer 51 is formed to cover at least the etched side surface of the gate electrode 31. The film formation can be performed in this way when using the CVD method and the like.

Then, as shown in FIG. 2H, the barrier material layer 51 is etched back, so that the barrier material layer 51 is remained on the side surfaces of the gate electrode 31 and the barrier material layer 51 on the gate oxide film 30, except for the region in which the gate electrode 31 is formed, can be etched. This shape can be implemented by using an anisotropic etching. For example, the etch back can be performed with the same condition as the dry etching in the process shown in FIG. 2D. Thereby, the sidewall barrier layer 42 remains only on the side surfaces of the gate electrode 31 (a sidewall barrier layer formation process).

Subsequently, as shown in FIG. 21, the interlayer insulation layer 32 is formed (an interlayer insulation layer formation process). Then, as shown in FIG. 2J, the photoresist layer 100, which is a mask for opening a contact portion of the interlayer insulation layer 32 with the n⁺⁺-type diffusion layer 24 becoming a source region, is formed.

As shown in FIG. 2K, the interlayer insulation layer is dry etched by using the photoresist layer 100 as a mask, so that an opening is provided above the n⁺⁺-type diffusion layer 24. At this state, as shown in FIG. 2L, a silicide electrode material layer 52 configured by the metal (for example, Ni, Ni silicide and the like) becoming the material of the silicide electrode 33 is formed on the entire surface by a vapor deposition method and the like. Thereby, it is possible to form the silicide electrode material layer 52 even on the n⁺⁺-type diffusion layer 24 in the opening.

After that, as shown in FIG. 2M, the photoresist layer 100 is removed to also remove the silicide electrode material layer 52 on the photoresist layer 100. At this state, a heat treatment causing a silicide reaction at an interface of the n⁺⁺-type diffusion layer 24 and the silicide electrode material layer 52 is performed to make the silicide electrode material layer 52 into the silicide electrode 33 (a silicide electrode formation process). The heat treatment is performed at temperatures of about 1,000° C. in an N₂ or Ar atmosphere or reduced-pressure atmosphere. A contact resistance between the n⁺⁺-type diffusion layer 24 and the silicide electrode 33 formed in this way is lowered. Upon the heat treatment, the metal configuring the silicide electrode material layer 52 (the silicide electrode 33) reacts with SiO₂ at a portion at which the silicide electrode material layer 52 and the interlayer insulation layer 32 (SiO₂) are contacted. Thereby, the metal elements may diffuse to the gate electrode 31 and the underlying gate oxide film 30. However, the diffusion is suppressed by the barrier layer 40 having the high barrier characteristic.

After that, as shown in FIG. 2N, the source electrode 34 having a two-layered structure in which a lower layer is the Ti layer 341 and an upper layer is the Al layer 342 is formed (a main electrode formation process), so that the semiconductor device 10 shown in FIG. 1 is obtained. In the above structure, the source resistance is reduced by interposing the silicide electrode 33.

In the above manufacturing method, a lithography for patterning the barrier layer 40 (the upper surface barrier layer 41 and the sidewall barrier layer 42) is not performed. The lithography is performed only twice for the pattering (FIG. 2D) in the gate electrode shape forming process and the patterning (FIG. 2K) of the interlayer insulation layer 32 in the silicide electrode formation process. In particular, since the upper surface barrier layer 41 exists integrally with the gate electrode 31 from the film formation thereof, the upper surface barrier layer 41 can be also shaped by using the same mask pattern. For this reason, it is possible to form the barrier layer 40 with the simple manufacturing method.

In the above illustrative embodiment, the barrier material layer 51 is etched back in the sidewall barrier layer formation process (FIG. 2H). However, the etch back is not necessarily required. That is, the barrier layer 40 can be arbitrarily configured inasmuch as the structure in which the upper surface of the gate electrode 31 and the side surface thereof facing the silicide electrode 33 are covered by the barrier layer 40 is implemented and a wiring structure connected to the gate electrode 31 is implemented. When the etch back is not performed or an amount of the etch back is small, a thickness (a vertical direction) of the upper surface barrier layer 41 is larger than a thickness (a horizontal direction) of the sidewall barrier layer 42. When the etch back is not performed, the manufacturing method is more simplified.

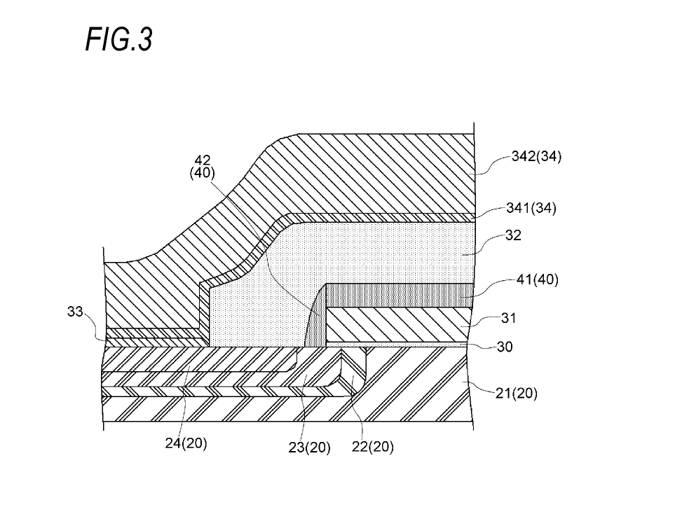

Also, in the gate electrode shape forming process of the above manufacturing method, it is shown in FIG. 2E that the gate oxide film 30 is not etched. However, the gate oxide film 30 can be also etched following the electrode material layer 50. Also in this case, the above manufacturing method can be also applied in the same manner, except for the etching of the gate oxide film 30. FIG. 3 is a sectional view of a semiconductor device manufactured according to this modified embodiment. In this case, not only the side surface of the gate electrode 31 but a side surface of the underlying gate oxide film 30 is covered by the sidewall barrier layer 42. For this reason, the negative influence of the metal on the gate oxide film 30 is further suppressed.

As described above, according to the above structure and manufacturing method, when forming the MOSFET on the semiconductor substrate made of SiC, it is possible to reduce the negative influence of the metal configuring the silicide electrode. Also, since it is possible to easily manufacture the corresponding structure, it is possible to obtain the MOSFET at low cost.

Also, since it is possible to reduce the negative influence of the metal configuring the silicide electrode on the gate electrode by the above configuration, it is possible to make a configuration where the silicide electrode and the gate electrode are formed to be close to each other. That is, according to the above structure and manufacturing method, it is possible to miniaturize the semiconductor device.

Meanwhile, in the above illustrative embodiment, the semiconductor substrate is made of SiC and the silicide electrode is formed of Ni silicide. However, it is obvious that even when the semiconductor substrate and the silicide electrode are made of different materials, for example, Si, the same effects can be obtained.

In the above illustrative embodiment, the semiconductor device is the MOSFET. However, it is obvious that the same structure and manufacturing method can be also applied to a semiconductor device having a gate electrode and a silicide electrode of the same structure formed on a surface thereof.

What is claimed is:

1. A method of manufacturing a semiconductor device that includes a gate oxide film, which is formed on a surface of a semiconductor substrate; a main electrode, which is formed on the surface and a current flowing through which is switched by a voltage applied to a gate electrode formed on the gate oxide film; and a silicide electrode is provided between the main electrode and the surface, the method comprising:
forming, sequentially, a gate electrode material layer made of a material configuring the gate electrode and a barrier material layer made of a silicon nitride film, on the gate oxide film;
forming an upper barrier layer configured to an upper surface of the gate electrode with the barrier material layer and forming the gate electrode from the gate electrode material later by etching the barrier material layer and the gate electrode material layer with a same mask pattern;
forming a sidewall barrier layer configured to cover a side surface of the gate electrode by forming again the barrier material layer after the forming of the gate electrode from the gate electrode material later;
forming an interlayer insulation layer configured to cover a surface-side of the semiconductor substrate including the upper surface barrier layer and the sidewall barrier layer; and
opening the interlayer insulation layer and then forming the silicide electrode on the surface of the semiconductor substrate.

2. The method of manufacturing a semiconductor device according to claim 1,
wherein in the forming of the sidewall barrier layer, the barrier material layer is etched back after forming again the barrier material layer.

3. The method of manufacturing a semiconductor device according to claim 1,
wherein in the forming of the gate electrode from the gate electrode material later, the gate oxide film is etched by using the same mask pattern after the etching of the gate electrode material layer.

4. The method of manufacturing a semiconductor device according to claim 1,
wherein the semiconductor substrate is made of silicon carbide.

5. The method of manufacturing a semiconductor device according to claim 1,
wherein the silicide electrode is made of nickel silicide.

6. A semiconductor device manufactured by the method of manufacturing the semiconductor device according to claim 1.

7. A semiconductor device comprising
a gate oxide film, which is formed on a surface of a semiconductor substrate;
a main electrode, which is formed on the surface and a current flowing through which is switched by a voltage applied to a gate electrode formed on the gate oxide film; and
a silicide electrode is provided between the main electrode and the surface,
wherein an upper surface of the gate electrode and a side surface of the gate electrode facing the silicide electrode are covered by a barrier layer made of a silicon nitride film.

8. The semiconductor device according to claim 7,
wherein the barrier layer on the upper surface of the gate electrode is thicker than the barrier layer on the side surface.

9. The semiconductor device according to claim 7,
wherein the semiconductor substrate is made of silicon carbide.

10. The semiconductor device according to claim 7,
wherein the silicide electrode is made of nickel silicide.
